(19) United States
(12) Patent Application Publication
(10) Pub. No.: US 2013/0017644 A1
(43) Pub. Date: Jan. 17, 2013

(54) Fluorine Based Chamber Clean With Nitrogen Trifluoride Backup

(71) Applicants: Robert Wiman Carter, III, Macungie, PA (US); Andrew David Johnson, Doylestown, PA (US); John Crawford Rossman, Orefield, PA (US)

(72) Inventors: Robert Wiman Carter, III, Macungie, PA (US); Andrew David Johnson, Doylestown, PA (US); John Crawford Rossman, Orefield, PA (US)

(73) Assignee: Air Products and Chemicals, Inc., Allentown, PA (US)

(21) Appl. No.: 13/353,729

(22) Filed: Jan. 19, 2012

Related U.S. Application Data
(60) Provisional application No. 61/444,353, filed on Feb. 18, 2011.

(51) Int. Cl. H05K 13/00; H01L 31/18

(52) U.S. Cl. 438/57; 427/58; 118/712; 257/E31.11

(57) ABSTRACT

The present invention is a process for cleaning a reaction chamber comprising the steps of;
(a) Providing a reaction chamber to deposit materials on a target substrate;
(b) Depositing the materials on the target substrate in an interior of the reaction chamber;
(c) Periodically discontinuing the depositing, and contacting the reaction chamber interior with a mixture of fluorine and nitrogen to clean the interior of the reaction chamber; and,
(d) when the mixture of fluorine and nitrogen is not available, switching to contacting the reaction chamber interior with nitrogen trifluoride.

An apparatus is also disclosed.

### CROSS REFERENCE TO RELATED APPLICATION

The present patent application claims the benefit of prior U.S. Provisional Patent Application Ser. No. 61/444,353 filed Feb. 18, 2011.

### BACKGROUND OF THE INVENTION

In the semiconductor, flat panel display and photovoltaic manufacturing industries, electronic devices are manufactured in a reaction chamber to deposit desired films. These depositions typically deposit in a non-selective manner, resulting in inadvertent deposits on the inside walls of the reaction chamber.

To maintain consistency in electronic device production, the inadvertent deposits on the inside walls of reaction chambers need to be removed periodically. Historically, reaction chambers were cooled to ambient temperatures, removed from the production line and subjected to acidic and basic liquid cleaning reagents.

An advance in the industry was the adoption of gaseous nitrogen trifluoride (NF₃) to clean reaction chambers at process conditions and without removal from the production line. This greatly enhanced the productivity of these reaction chambers and simplified the cleaning operation.

NF₃ is merely a convenient and relatively safe source of fluorine atoms, which is the actual specie performing the in-situ cleaning of reaction chambers. NF₃ is capable of being transported in public regulated transportions modes, unlike elemental fluorine, which is severely limited in quantities that can be transported, due to its corrosive, toxic and oxidative properties.

NF₃ is merely used to provide safe, large volume transport and then at the reaction chamber is decomposed to fluorine and nitrogen atoms during the clean process of a reaction chamber. This is performed typically by a remote plasma chamber upstream of the reaction chamber to be cleaned. The NF₃ is decomposed to nitrogen and fluorine atoms, and these fluorine atoms react with the inadvertent depositions on the inside wall of the reaction chamber to remove the deposits. For silicon-based deposits, this results in a SiF₄ gaseous by-product, which is removed from the reaction chamber and treated in downstream abatement systems, as a waste.

The drawback to NF₃ is its cost and periodic supply constraints. Suppliers of raw materials and consumable chemicals to the electronic device manufacturing industry sought ways to avoid NF₃'s high cost and the regulatory restraints on fluorine transportation and use, by providing fluorine production on-site at the customers site, thus avoiding transportation of significant quantities of fluorine and avoiding significant storage of fluorine.

Fluorine production is typically performed by electrolytic decomposition of hydrogen fluoride (HF) to form di-atomic fluorine or F₂. The electrolytic cells in which HF is converted to F₂ are well known and have been operated for years. Despite this track record, any manufacturing system, including on-site fluorine electrolytic cells, are subject to periodic maintenance or non-planned outages. Thus, an electronic device manufacturer that needs to periodically clean its many reaction chambers, requires a steady, consistent supply of fluorine to avoid an expensive reaction chamber shutdown, if cleaning gas is not available for even short time periods.

Electronic device manufacturers, thus, have been unwilling to change from readily transported and volume storable NF₃ to F₂, unless backup cleaning gas is available in the event that the on-site fluorine cells go off line for any reason. Various on-site fluorine cell systems with backup contingencies have been consider by the industry, including more fluorine cells than are required for steady state capacity, on-site fluorine storage, alternate sources of fluorine or fluorine generating molecules and even NF₃ itself.

The type of reaction chambers that may be cleaned periodically with fluorine or NF3 or both include reaction chambers using: chemical vapor deposition (CVD), plasma enhanced chemical vapor deposition (PECVD), low pressure chemical vapor deposition (LPCVD), continuous chemical vapor deposition (CCVD), atomic layer deposition (ALD) and the various manifestations of combinations and derivatives of those reaction modes. These reaction chambers can be cleaned using fluorine plasmas. Although NF₃, a non-reactive compressed gas, is a convenient source of fluorine, F₂-based processes have been shown to have a lower cost. Elemental F₂ is corrosive, toxic and a strong oxidizer. Consequently, F₂ handling is problematic and regulations restrict the quantities of F₂ that may be transported. On-site generation of F₂ through electrolysis of anhydrous HF overcomes many of these difficulties. F₂ manufacturing requires a complex chemical-plant, however, and backup is needed for times when the plant undergoes maintenance. While gaseous F₂ storage can provide limited backup, this is not sufficient for extended down-times.

Prior art in the field of this invention includes US2005/0161321.

The present invention overcomes the difficulties in on-site use of fluorine cells to provide fluorine in a safe, continuous, regulation compliant manner, by using backup NF₃, but in a manner which facilitates the electronic device manufacturer's switching between fluorine and NF₃ and back again without complication and without process variations, so that dependable consistent production and cleaning of reaction chambers is maintained, as will be described in greater detail below.

### BRIEF SUMMARY OF THE INVENTION

The present invention is a process for cleaning a reaction chamber comprising the steps of;

(a) Providing a reaction chamber to deposit materials on a target substrate;
(b) Depositing the materials on the target substrate in an interior of the reaction chamber;
(c) Periodically discontinuing the depositing;
(d) contacting the reaction chamber interior with a mixture of fluorine and nitrogen to clean the interior of the reaction chamber; and,
(e) when the mixture of fluorine and nitrogen is not available, switching to contacting the reaction chamber interior with nitrogen trifluoride.

Alternately, the present invention is a process of cleaning a reaction chamber interior with fluorine, the improvement comprising using a mixture of fluorine and nitrogen and switching the cleaning to use nitrogen trifluoride.

Preferably, an argon diluents is used with the mixture of fluorine and nitrogen and the nitrogen trifluoride. Preferably, a nitrogen diluents is used with the nitrogen trifluoride in addition to the nitrogen diluents.

The present invention is also an apparatus for electronic device manufacture, comprising;

(a) A reaction chamber for depositing a silicon containing material on a target in the interior of the reaction chamber;
(b) A source of fluorine gas in fluid flow communication with the interior of the reaction chamber;
(c) A source of nitrogen in fluid flow communication with the interior of the reaction chamber;
(d) A source of nitrogen trifluoride in fluid flow communication with the interior of the reaction chamber;
(e) a mixer for blending the fluorine and nitrogen in fluid flow communication with the source of fluorine, in fluid flow communication with the source of nitrogen and in fluid flow communication with the interior of the reaction chamber;
(f) a sensor capable of detecting the condition of the source of fluorine for upset conditions;
(g) a switch in fluid flow communications with the source of fluorine, the source of nitrogen, the source of nitrogen trifluoride and the interior of the reaction chamber and in signal communiation with the sensor, and capable of switching the fluid flow communication of the reaction chamber from the source of fluorine and the source of nitrogen to the source of nitrogen trifluoride upon receipt of a signal from the sensor.

### BRIEF DESCRIPTION OF SEVERAL VIEWS OF THE DRAWINGS

FIG. 1 is a graph of SiF₄ concentrations during the cleaning cycle of a TEOS-based SiO₂ deposition chamber using fluorine/nitrogen/argon (F₂-1) contrasted to the same clean cycle using nitrogen trifluoride/nitrogen/argon (NF₃-1) of Table 1 measured by Fourier Infrared Spectroscopy (FTIR), showing equivalency of the expected by-product, SiF₄.

FIG. 2 is a graph of SiF₄ concentrations during the cleaning cycle of a TEOS-based SiO₂ deposition chamber using fluorine/nitrogen/argon (F₂-2) contrasted to the same clean cycle using nitrogen trifluoride/nitrogen/argon (NF₃-2) of Table 1 measured by Fourier Infrared Spectroscopy (FTIR), showing the equivalency of the expected by-product, SiF₄.

### DETAILED DESCRIPTION OF THE INVENTION

This disclosure identifies a reaction chamber clean process that is identical using either NF₃ or F₂ as a fluorine source; i.e., switching between NF₃ and F₂ is transparent to the reaction chamber, such as a PECVD tool. This invention is particularly useful for operators that use large reaction chambers, such as thin film transistor flat panel display manufacturers that make television screens using very large reaction chambers and photovoltaic cell manufacturers that make solar panels, which also require very large reaction chambers. Both of these industries use relatively large quantities of clean gas, whether it is the more traditional NF₃ or the more recent on-site generated fluorine. In each instance, the large volume of clean gas use, makes these manufacturers interested in the lowest cost of clean gas. It has been shown that on-site electrolytic fluorine cell generation is cheaper for large volume consumption, than the historic NF₃ use. None-the-less, onsite electrolytic fluorine cell generation of fluorine still requires backup to assure continuous supply of clean gas, so as not to shutdown the expensive and elaborate electronic device reaction chambers.

NF₃ is an ideal back-up for the on-site F₂ generator since can be completely dissociated into F and N atoms by the plasma source. The significant conception of the present inventors to make switching from elemental fluorine to NF₃ and back “transparent” and process-equivalent for the operator, the reaction chamber and the electronic device product production is that by adding N₂ to the F₂-gas during normal clean cycles, the gas composition downstream of the plasma source is identical using either F₂ or NF₃. It is possible therefore to switch between F₂ and NF₃ by choosing a composition and flow-rate that provides an equivalent flowrate of F-atoms and N-atoms. The flow rate of the cleaning gases is typically controlled using mass flow controllers (MFCs). The sensitivity of a MFC may be different for each cleaning gas. For example, a MFC designed to supply 1.0 slm of F₂/N₂ will only supply 0.5 slm of NF3 under identical conditions. Gas correction factors, which relate to the heat capacity of the cleaning gas, are used to account for these differing sensitivities of the MFCs. The molecular composition of the cleaning gas determines how may fluorine atoms each molecule of cleaning gas supplies to the reaction chamber. Each F₂ molecule supplies 2 fluorine atoms. Each NF₃ molecule supplies 3 fluorine atoms. The chosen gas composition must account for the differing MFC gas-correction factors of NF₃ (0.5) and F₂/N₂ (1.0) and stoichiometry of F₂, N₂, and NF₃. The preferred composition is F₂ (75%)/N₂ and NF₃ (100%).

At low flow rates, clean-times are equivalent when the F-atom flow rates are the same; i.e., the time needed to remove residues is the same irrespective of whether F₂/N₂ or NF₃ is the cleaning gas as long as the same amount of F-atoms are supplied to the reaction chamber. At high flow rates, however, the cleaning gases may not be completey dissociated into F-atoms and N-atoms since N₂ is a sink that wastes plasma power and there may be no excess radio frequency (RF) power.

The following are experimental examples for removing residues from a PECVD reaction chamber using comparative processes. In all of the following experiments, the surface of the CVD chamber was coated with residues generated by depositing silicon dioxide films on silicon wafers. Tetraethoxysilicate (TEOS) was used to deposit the films in a PECVD process chamber: TEOS (1000 milligrams per minute (mgm)), O₂ (1000 standard cubic centimeters per minute (sccm)), He (1000 sccm), 8.2 torr, 400° C., 280 mils, 910 watts (W). The film thickness of each film was measured and found to be approximately 174-207 nanometers (nm). The refractive index of the film was measured and found to approximately 1.454-1.471. Film thickness and refractive index were measured by reflectometry techniques.

The examples were processed using an Applied Materials P-5000 DxZ PECVD reactor or process chamber having a remote plasma source (an MKS Astron-Ex, available from MKS Instruments of Wilmington, Mass.). The process chamber contained a base pedestal or bottom electrode, a top electrode connected to radio frequency (RF) power, a gas inlet for the flow of process gases, and an outlet that is connected to a vacuum pump. The walls of the chamber were grounded and maintained at a temperature of 75° C., and the chamber internals, such as the susceptor, were maintained at a temperature of 400° C. After depositing a TEOS film, the 200 mm silicon wafer was removed from the PECVD chamber, and the chamber cleaned of the residues.

Remote plasma cleaning experiments were conducted using the Applied Materials P-5000 DxZ PECVD chamber that was retrofitted with an Astron-Ex remote plasma source from MKS Corporation. After depositing a silicon dioxide film, the silicon wafer was removed from the PECVD chamber and the chamber cleaned of residues. This process was repeated. After evacuating the reactor, a process gas is introduced into the Astron-EX remote plasma generator. The chamber pressure is then stabilized and the remote source is turned on by applying RF power. It is believed that the intense plasma breaks down molecules of the process gas, which flow downstream through a connecting metal tube, and then, through the showerhead into the chamber and react with the residues on the chamber surfaces. The volatile compounds formed by the reactions between the reactive species and residues are removed from the reactor through the vacuum port. The process chamber was cleaned for approximately 200-260 seconds after each deposition using the various processing recipes and parameters provided in Table 1.

TABLE 1
Chamber Clean Process Parameters

| Clean | NF₃ | F₂(20%)/N₂ | N₂ | Ar | Pressure | F-atom | N-atom |
|---|---|---|---|---|---|---|---|
| # | (sccm) | (sccm) | (sccm) | (sccm) | (torr) | (sccm) | (sccm) |
| NF₃-1 | 139 | | 833 | 600 | 2.0 | 417 | 1667 |
| NF₃-2 | 280 | | 1666 | 600 | 2.0 | 842 | 3367 |
| F₂-1 | | 1010 | | 600 | 2.0 | 417 | 1667 |
| F₂-2 | | 2100 | | 600 | 2.0 | 842 | 3367 |

The example chamber clean processes were monitored by Fourier Transform Infrared Spectroscopy (FTIR) at the pump exhaust. This process analysis was used to identify byproducts of the chamber clean, measure process emissions, and determine clean times. Emissions measurements were made downstream of the process pump by extractive FTIR spectroscopy (MKS Multigas, Model 2010) using a HgCdTe detector and a heated 0.01 m gas cell. The process was sampled through a ¼ inch compression fitting at the exhaust of the process pump. The gases of interest are consequently diluted by the N₂ pump purge (50 to 70 slm). Process effluents were extracted from the pump exhaust using a metal diaphragm pump. Sample lines were ⅛-inch stainless steel tubing heat traced to approximately 100° C. Sample gas was pumped through the FTIR cell before being returned to a ventilated exhaust. The temperature and pressure of the gas cell was controlled at 150° C. and 1.0 atmosphere, respectively. Reported concentrations are corrected for temperature and pressure during the measurement. Absorbance spectra were collected at 0.5 cm⁻¹ resolution, averaged over 8-64 scans.

### Example 1

### Proof of Equivalence NF₃ and F₂-Based Processes

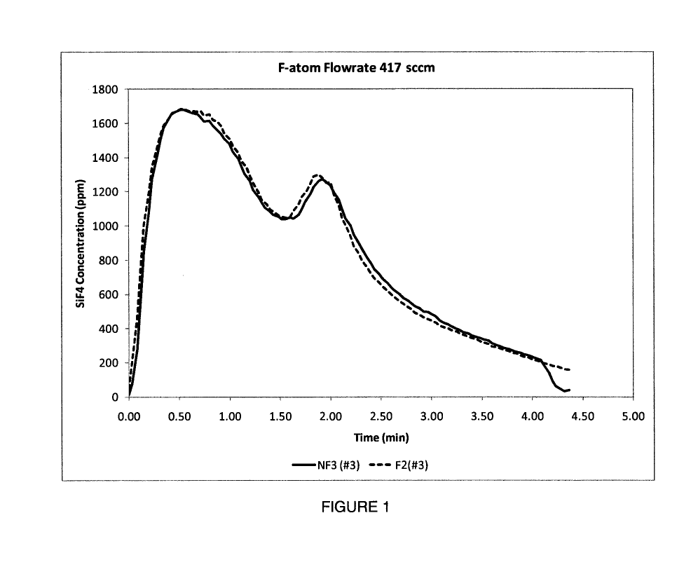

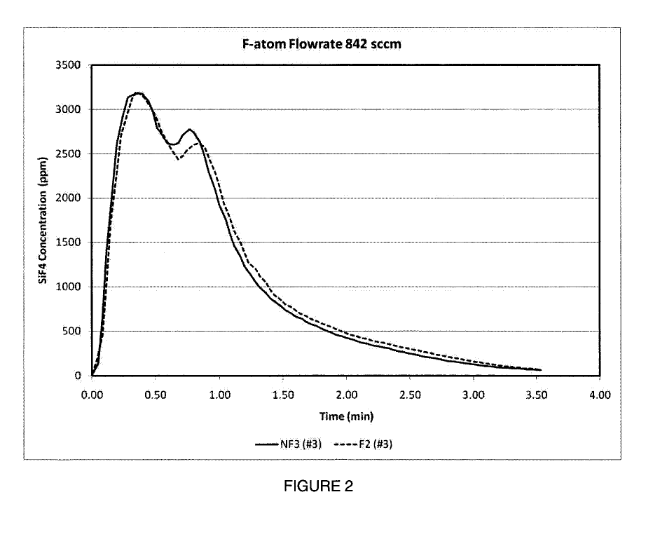

The atomic composition of clean gas NF₃-1 is identical to that of clean F₂-1 (Table 1). Similarly, cleans NF₃-2 and F₂-2 are identical. If the plasma source completely dissociates the process gases (NF₃, F₂, and, N₂), then the atomic composition of these processes are indistinguishable. Since, the primary etchant of the silicon dioxide residues are believed to be fluorine atoms, clean processes NF₃-1 and NF₃-2 are expected to be identical to clean processes F₂-1 and F₂-2, respectively. The SiF₄ clean by-product concentration profiles, measured by FTIR, for clean processes NF₃-1 and F₂-1 are shown in FIG. 1. The SiF₄ concentration profiles, measured by FTIR, for clean processes NF₃-2 and F₂-2 are shown in FIG. 2.

In both examples, the clean is started at time 0.00. As the silicon oxide residue is volatized as SiF₄, its concentration increases. Once the entire silicon dioxide residue has been removed from the chamber, SiF₄ concentrations return to baseline levels. The SiF₄ clean by-product profiles for clean NF₃-1 and F₂-1 (FIG. 1) are indistinguishable, demonstrating the clean times and SiF₄ emissions (Table 2) are identical. These clean processes have identical atomic composition (fluorine-atom flowrate 417 sccm, nitrogen-atom flowrate 1667 sccm. Similarly, the SiF₄ profiles for clean NF₃-2 and F₂-2 (FIG. 2) are indistinguishable, demonstrating the clean times and SiF₄ emissions (Table 2) are identical. These clean processes have identical atomic composition (fluorine-atom flowrate 842 sccm, nitrogen-atom flowrate 3367 sccm).

TABLE 2

| | |
|---|---|
| | SiF₄ emissions |
| F-atm flowrate | (scc) |

| (sccm) | NF₃-clean | F₂-clean |
|---|---|---|
| 417 sccm | 216 | 219 |
| 842 sccm | 211 | 217 |

Integrating under the SiF₄ profiles (FIGS. 1 and 2) allows the volumetric SiF₄ emissions to be calculated. SiF₄ emissions are a measure of clean-effectiveness. Since the residue is volatized as SiF₄, identical SiF₄ emissions confirm that an equivalent amount of silicon dioxide residue has been removed from the chamber. The SiF₄ emissions for all clean processes are summarized in Table 2. For the same fluorine-atom throughput, the NF₃ cleans (NF₃-1 and NF₃-2) remove the amount of residue as the F₂cleans (F₂-1 and F₂-2).

### Example 2

### Transparent Supply of Cleaning Gas

This disclosure identifies a chamber clean process that is identical using either NF₃ or F₂ as a fluorine source; i.e., switching between NF₃ and F₂ is transparent to the PECVD tool. NF₃ is an ideal back-up for the on-site F₂ generator since it may be completely dissociated into fluorine and nitrogen-atoms by the plasma source. By adding N₂ to the F₂-gas, the gas composition downstream of the plasma source is identical using either F₂ or NF₃. It is possible therefore to switch between F₂ and NF₃ by choosing a composition and flow-rate that provides an equivalent flowrate of F-atoms and N-atoms. The composition must also account for the differing MFC gas-correction factors of NF₃ (0.5) and F₂/N₂ (1.0) and stoichiometry of the cleaning gases F2 and NF3. The preferred composition is F₂ (75%)/N₂ and NF₃ (100%).

1. A process for cleaning a reaction chamber comprising the steps of;
(a) Providing a reaction chamber to deposit materials on a target substrate;
(b) Depositing the materials on the target substrate in an interior of the reaction chamber;
(c) Periodically discontinuing the depositing;
(d) contacting the reaction chamber interior with a mixture of fluorine and nitrogen to clean the interior of the reaction chamber; and,
(e) When the mixture of fluorine and nitrogen is not available, switching to contacting the reaction chamber interior with nitrogen trifluoride.

2. The process of claim 1 wherein a nitrogen diluent is added to the nitrogen trifluoride.

3. The process of claim 1 wherein a diluent of argon is added to the mixture of fluorine and nitrogen and to the nitrogen trifluoride.

4. The process of claim 1 wherein the mixture of fluorine and nitrogen is 75% by volume fluorine.

5. The process of claim 1 wherein the nitrogen trifluoride is 100% nitrogen trifluoride.

6. The process of claim 1 wherein the target substrate is removed from the reaction chamber before contacting with the mixture of fluorine and nitrogen.

7. The process of claim 1 wherein the target substrate is removed from the reaction chamber before contacting with the nitrogen trifluoride.

8. In a process of cleaning a reaction chamber interior with fluorine, the improvement comprising using a mixture of fluorine and nitrogen and switching the cleaning to use nitrogen trifluoride.

9. The process of claim 8 wherein the mixture of fluorine and nitrogen is 75% by volume fluorine.

10. The process of claim 9 wherein the nitrogen trifluoride is 100% nitrogen trifluoride.

11. The process of claim 8 wherein the switching is performed when the desired mixture of fluorine and nitrogen is not available.

12. The process of claim 1 wherein the depositing is a process of producing a flat panel display.

13. The process of claim 1 wherein the depositing is a process of producing a photovoltaic cell.

14. An apparatus for electronic device manufacture, comprising;
(a) A reaction chamber for depositing a silicon containing material on a target in the interior of the reaction chamber;
(b) A source of fluorine gas in fluid flow communication with the interior of the reaction chamber;
(c) A source of nitrogen in fluid flow communication with the interior of the reaction chamber;
(d) A source of nitrogen trifluoride in fluid flow communication with the interior of the reaction chamber;
(e) a mixer for blending the fluorine and nitrogen in fluid flow communication with the source of fluorine, in fluid flow communication with the source of nitrogen and in fluid flow communication with the interior of the reaction chamber;
(f) a sensor capable of detecting the condition of the source of fluorine for upset conditions;
(g) a switch in fluid flow communications with the source of fluorine, the source of nitrogen, the source of nitrogen trifluoride and the interior of the reaction chamber and in signal communiation with the sensor, and capable of switching the fluid flow communication of the reaction chamber from the source of fluorine and the source of nitrogen to the source of nitrogen trifluoride upon receipt of a signal from the sensor.
